(19) United States
(12) Patent Application Publication
(10) Pub. No.: US 2019/0360858 A1
(43) Pub. Date: Nov. 28, 2019

(54) MICROMECHANICAL MODULE AND METHOD FOR DETECTING OSCILLATIONS, IN PARTICULAR STRUCTURE-BORNE SOUND

(71) Applicant: Robert Bosch GmbH, Stuttgart (DE)

(72) Inventor: Mathias Bruendel, Reutlingen (DE)

(21) Appl. No.: 16/479,418

(22) PCT Filed: Jan. 10, 2018
(86) PCT No.: PCT/EP2018/050534

§ 371 Date: Jul. 19, 2019

(30) Foreign Application Priority Data
Jan. 31, 2017 (DE) 10 2017 201 481.4

(51) Int. Cl. G01H 1/00; B81B 7/02

(52) U.S. Cl. CPC G01H 1/00; B81B 7/02; B81B 2207/012; B81B 2201/0257; B81B 2201/0235

(57) ABSTRACT

A micromechanical module us described for placement on a body for acquiring oscillations in the body, including a housing having a cavity, the cavity being an acoustically operative volume, a substrate, a microphone that is acoustically coupled to the cavity and is set up to acquire transverse waves of the oscillations, and a MEMS acceleration sensor, the MEMS acceleration sensor being set up to acquire longitudinal waves of the oscillations along at least one measurement axis parallel to a surface of the body, and the substrate connecting the microphone and the MEMS acceleration sensor to one another electrically and mechanically, and having a common interface for the output.

### FIELD OF THE INVENTION

The present invention relates to a micromechanical module and to a method for acquiring oscillations in a body at a surface of the body, so-called structure-borne sound, in particular for acquiring transverse and longitudinal waves of the oscillations.

### BACKGROUND INFORMATION

From the existing art, various micromechanical modules and systems are known for the measurement of oscillations.

Micromechanical modules (MEMS modules) and systems are suitable for use wherever a small amount of space is available for a relatively complex technical task. They can be used in mobile communication devices, in fitness equipment, and in other modern sensor systems.

From German Published Patent Application No. 10 2014 100 464, a device is disclosed having a plurality of micromechanical microphones, used for example as stereo microphones.

German Published Patent Application No. 102011 055523 describes a method and a device for acquiring structure-borne sound, in which only those oscillations are acquired whose amplitude exceeds a threshold value.

Also known is a crash recognition system in an automobile based on measurements of structure-borne sound. Structure-borne sound sensors can be a component of the electronics for activating restraint systems, such as airbags and safety belts. The plastic deformation of the structure is acquired by measuring the characteristics structure-borne sound that occurs during a crash. At the same time, various crash scenarios, such as high or low speed, partial vehicle overlapping, oblique impact, and impact against highly deformable objects, can be well distinguished from one another.

In fitness equipment, micromechanical modules are used for example to acquire a movement or to acquire the cardiac frequency of a user.

### SUMMARY

According to an embodiment of the present invention, a micromechanical module is to be placed on a body for acquiring oscillations in the body, including a housing having a cavity, the cavity being an acoustically operative volume, the housing also having a substrate, a microphone coupled acoustically to the cavity and set up to acquire transverse waves of the oscillations, and a MEMS acceleration sensor, the MEMS acceleration sensor being set up to acquire longitudinal waves of the oscillations along at least one measurement axis parallel to a surface of the body, and the substrate connecting the microphone and the MEMS acceleration sensor to one another electrically and mechanically and having a common interface for output.

Also provided is:

A method for acquiring oscillations in a body at a surface of the body, including the acquisition of transverse waves of the oscillations by a microphone, the acquisition of longitudinal waves of the oscillations by a MEMS acceleration sensor, and outputting measurement values of the acquired transverse and longitudinal waves via a common interface.

The finding on which the present invention is based is that oscillations in bodies that are to be characterized have a longitudinal component and a tangential component that are propagated differently in the body and have to be acquired by different measurement systems.

The present invention takes into account this finding and provides a micromechanical module according to the present invention that acquires longitudinal oscillations using a MEMS acceleration sensor and acquires transverse oscillations using a microphone.

Advantageous specific embodiments and developments result from the subclaims and from the description, with reference to the Figures.

In addition, a specific embodiment includes an evaluation unit, the evaluation unit being set up to combine measurement values of the acquired longitudinal and transverse waves and to output the combined measurement values in a common output signal. This simplifies the further processing of the acquired data, because only a combined set of acquired oscillations has to be further processed.

A further specific embodiment is designed in such a way that the evaluation unit outputs the common output signal wirelessly. In this way, the number of required cables is reduced, and in addition the space required for the cables is saved, so that the micromechanical module reduces the outlay during cabling and at the same time requires less space, and thus can be used at locations that would not be reachable for larger modules with cabling. Overall, a simplification of the cabling and of the reading out of a plurality of micromechanical modules is achieved. In a further specific embodiment, the microphone and/or the MEMS acceleration sensor output digital output signals. Digital output signals are less susceptible to interference during transmission, and therefore improve the signal-to-noise ratio.

In a further specific embodiment, the MEMS acceleration sensor is optimized for a first frequency range and the microphone is optimized for a second frequency range different from the first frequency range. Especially in applications in which frequency ranges of the oscillations to be acquired are known, the signal-to-noise ratio can be improved through an optimization of the frequency response of the micromechanical module.

In a further specific embodiment, the MEMS acceleration sensor is optimized for a frequency range between 20 kHz and 100 kHz, while the microphone is optimized in the frequency range up to 20 kHz. In this way, the micromechanical module enables the recording of longitudinal oscillations in the audible spectrum and the recording of transverse oscillations in the ultrasound range.

In a further specific embodiment, the MEMS acceleration sensor has two measurement axes perpendicular to one another, which are oriented parallel to the surface when the micromechanical module is placed on the surface of the body. Through the use of a MEMS acceleration sensor having two measurement axes, the components of longitudinal oscillations in a plane can be acquired, and in this way a direction of propagation of the longitudinal oscillations can be determined. Alternatively, however, various superposed longitudinal oscillations having different directions of propagation can be acquired.

In a further specific embodiment, the MEMS acceleration sensor has two MEMS acceleration modules each having a measurement axis, the two measurement axes being perpendicular to one another and being situated parallel to the surface when the micromechanical module is placed on the surface of the body. Through the use of two MEMS acceleration modules, these two MEMS acceleration modules can be matched precisely to the corresponding application, in this way optimizing the sensitivity and the signal-to-noise ratio.

In a further specific embodiment, the method has a combination of the measurement values of the acquired transverse and longitudinal waves before outputting, the combined measurement values being outputted as a common output signal. This simplifies the further processing of the acquired data, because only one set of combined measurement values of acquired oscillations has to be further processed.

In a further specific embodiment, the outputting takes place wirelessly. In this way, a simplification of the cabling and of the reading out of a plurality of micromechanical modules is achieved.

In a further specific embodiment, the acquisition of the transverse waves includes a digitization of the measurement values and/or the acquisition of the longitudinal waves includes a digitization of the measurement values.

### BRIEF DESCRIPTION OF THE DRAWINGS

FIG. 1 shows a schematic representation of a specific embodiment of a micromechanical module according to the present invention.

FIG. 2 shows a schematic representation of a measurement process using a specific embodiment of a micromechanical module according to the present invention.

FIG. 3 shows a schematic representation of a specific embodiment of a micromechanical module according to the present invention.

FIG. 4 shows a schematic representation of a specific embodiment of a micromechanical module according to the present invention.

FIG. 5 shows a schematic representation of a specific embodiment of a micromechanical module according to the present invention.

FIG. 6 shows a schematic flow diagram of a specific embodiment of a method for acquiring oscillations in a body.

### DETAILED DESCRIPTION

In all the Figures, identical or functionally identical elements and devices have been provided with the same reference characters, unless otherwise indicated. The numbering of method steps is provided for clarity, and is in particular not intended to imply a particular temporal sequence, unless otherwise indicated. In particular, a plurality of method steps may also be carried out simultaneously.

Although the present invention has been described above on the basis of preferred exemplary embodiments, it is not limited thereto, but rather may be modified in various ways. In particular, the present invention may be modified in many ways without departing from the core of the present invention.

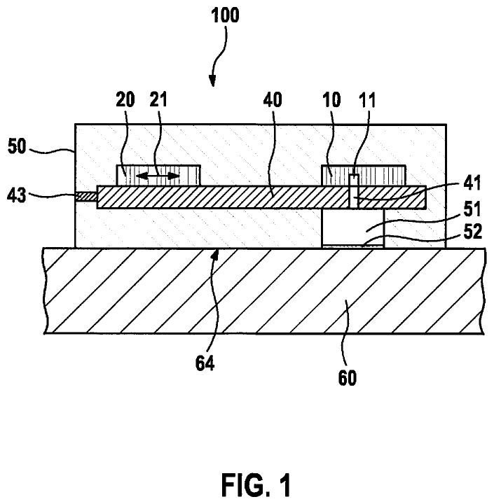

FIG. 1 shows a schematic representation of a specific embodiment of a micromechanical module (MEMS module) 100 according to the present invention for acquiring structure-borne sound, the structure-borne sound being composed of longitudinal and transverse waves.

Micromechanical module 100 has a housing 50, a substrate 40, a MEMS acceleration sensor 20, and a microphone 10. Optionally, micromechanical module 100 also has an evaluation unit 30 (not shown in FIG. 1).

Housing 50 provides mechanical protection for micromechanical module 100, mechanical attachment of the micromechanical module to body 60, and acoustic coupling of body 60 to microphone 10 via housing 50. Housing 50 can for example be a shell construction of plastic, metal, and/or a composite material, or can be made of a solid material, e.g. a casting or injection compound known from electronics. Housing 50 has a cavity 51. Cavity 51 is used by microphone 10 as an acoustically operative volume. The shape and size of cavity 51 are adapted to the type and shape of microphone 10. If for example microphone 10 is a MEMS microphone, then, depending on the constructive shape and position of the MEMS microphone in housing 50, a hollow space is required before and/or after a membrane of microphone 10, this space forming a front and/or rear volume of microphone 10.

According to the specific embodiment in FIG. 1, cavity 51 is a front volume of microphone 10. The size and geometry of cavity 51 can for example also have an influence on a resonance characteristic of microphone 10, and can be designed to correspond to a desired resonance. By enlarging the front volume, the Helmholtz resonance frequency can be shifted towards lower frequencies, and by making the front volume smaller it can be shifted towards higher frequencies. Enlarging the rear volume makes it easier to move a membrane of microphone 10, so that enlarging the rear volume increases the sensitivity of microphone 10. A sealing of cavity 51 can be done for example by a film 52. The film would have no influence on the quality of the acoustic coupling, but would provide further mechanical protection e.g. against penetrating dust or the like. Alternatively, the sealing of cavity 51 can however also be achieved through sealing relative to surface 64 of the body, e.g. using an adhesive or glue or using sealing means such as a rubber lip or an O-ring, for example pressed on when the micromechanical module is pressed onto body 60 and thus sealing cavity 51.

Substrate 40 connects MEMS acceleration sensor and microphone 10 to one another electrically and mechanically. An outputting of acquired measurement values takes place via a common interface 43, optionally via an evaluation unit 30 (not shown in FIG. 1) optionally situated on substrate 40. According to the specific embodiment in FIG. 1, substrate 40 has an opening 41 situated at cavity 51 that enables an acoustic coupling of body 60 to microphone 10. Substrate 40 is for example a simple circuit board, an SMD circuit board, or a multilayer circuit board. The overall interface 43 can for example be a CAN bus interface, a USB interface, an Ethernet interface, or any other standard wire-bound data bus. Alternatively, the overall interface can however also have a wireless connection, for example via Bluetooth, WLAN, or also via RFID or a mobile radiotelephone module.

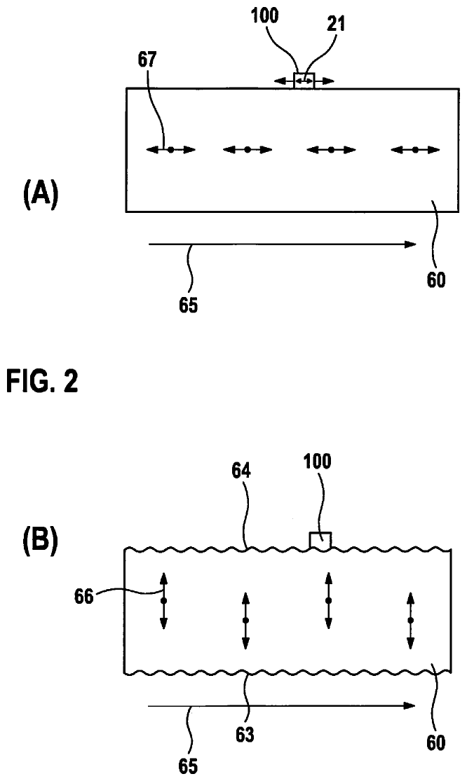

A MEMS acceleration center 20 is situated on the side of substrate 40 facing body 60 in such a way that when the micromechanical module is placed on surface 64 of the body, at least one measurement axis 21 of the sensor is parallel to surface 64. Alternatively, MEMS acceleration sensor 20 can also have two measurement axes perpendicular to one another, the two measurement axes spanning a plane parallel to surface 64. MEMS acceleration center 20 acquires the longitudinal waves of the structure-borne sound, as shown in FIG. 2. The measurement values of the acquired longitudinal waves are for example outputted in analog fashion by MEMS acceleration sensor 20; alternatively, a digitization of the measurement values can take place already in MEMS acceleration sensor 20.

Microphone 10 is also situated on the side of substrate 40 facing away from body 60, and is acoustically coupled to body 60 by cavity 51 and opening 41. Microphone 10 is fashioned for example as a MEMS microphone, and has a hollow space 11 that forms a rear volume of the

MEMS microphone. Depending on the design of the MEMS microphone, the hollow space can however also be a front volume of the MEMS microphone. Through the acoustic coupling to body 60, microphone 10 can acquire the transverse waves of the structure-borne sound. According to FIG. 1, microphone 10 is a bottom-port MEMS microphone. Alternatively, however, given a suitable choice of the geometry of cavity 51, a top-port MEMS microphone can also be used, or a mixed form of the two may be used. The measurement values of the acquired transverse waves are outputted for example in analog fashion by microphone 10; alternatively, a digitization of the measurement values can already take place in microphone 10.

FIGS. 2A and 2B are intended to represent the acquisition of the structure-borne sound with a micromechanical module 100 on a body 60.

In FIG. 2A, arrows 67 indicate a longitudinal oscillation in body 60 having a direction of propagation 65. Micromechanical module 100 oscillates corresponding to the longitudinal oscillation of body 60 and MEMS acceleration sensor 20 acquires a component of the longitudinal wave of the structure-borne sound parallel to the at least one measurement axis 21 of the MEMS acceleration sensor.

In FIG. 2B, arrows 66 and wavy surfaces 63 and 64 indicate a transverse oscillation in body 60 having direction of propagation 65. Microphone 10 of micromechanical module 100 is acoustically coupled to body 60 via cavity 51 and opening 41, and in this way can acquire the transverse waves of the structure-borne sound.

Both microphone 10 and MEMS acceleration center 20 can be optimized with regard to their response for particular frequency ranges. For example, microphone 10 can be optimized for the audible frequency range between 20 Hz and 20 kHz, and MEMS acceleration sensor 20 can be optimized for the frequency range between 20 kHz and 100 kHz, and can thus also acquire ultrasound. If, in contrast, it is known that longitudinal oscillations in body 60 occur in the frequency range between 20 Hz and 20 kHz and transverse oscillations in the body occur in the frequency range between 20 kHz and 100 kHz, then micromechanical module 100 is designed so that the MEMS acceleration sensor is optimized for the frequency range between 20 Hz and 20 kHz and microphone 10 is optimized for the frequency range between 20 kHz and 100 kHz. Correspondingly, for each application, if the expected frequency range is known, a correspondingly optimized microphone 10 and a correspondingly optimized MEMS acceleration sensor 20 can be selected.

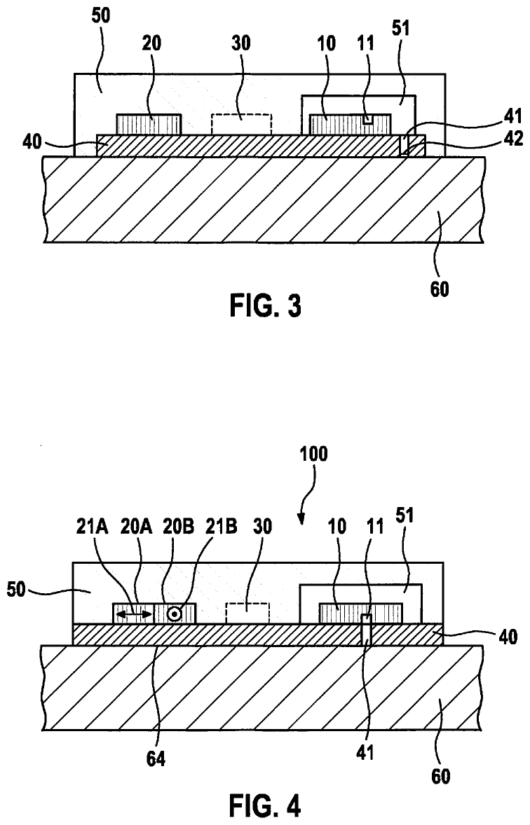

FIG. 3 shows a specific embodiment that has been modified relative to the specific embodiment of FIG. 1 in that here housing 50 is not, or is not only, situated on the body; rather substrate 40 is also, or is exclusively, situated directly on body 60. Moreover, the position of cavity 51 is changed in that it is no longer situated below substrate 40, but rather above it. In addition, instead of a bottom-port MEMS microphone, a top-port MEMS microphone is used. The top-port MEMS microphone is not coupled directly acoustically to opening 41 in substrate 40; rather, opening 41 is acoustically coupled to cavity 51, and this cavity in turn is coupled to the top-port MEMS microphone. Opening 41 is sealed by a foil 42. This specific embodiment enables a slimmer shape compared to the specific embodiment of FIG. 1.

The specific embodiment in FIG. 3 shows evaluation unit 30 over substrate 40. Evaluation unit 30 combines measurement values of the longitudinal and transverse oscillations acquired by the MEMS acceleration sensor and microphone 10, and outputs the combined measurement values in a common output signal. The output takes place via common interface 40 (not shown). Evaluation unit 30 is for example a microcontroller unit, but alternatively may also be a microcontroller unit combined with a wireless transmission interface. If evaluation unit 30 is a microcontroller unit, then evaluation unit 30 can also carry out an analysis of the measurement values, or can carry out a first data selection, e.g. according to specified conditions.

The specific embodiment of FIG. 4 differs from the specific embodiment of FIG. 3 in that microphone 10 is a bottom-port MEMS microphone and is acoustically directly coupled to opening 41 in substrate 40. In this specific embodiment, cavity 51 acts as a rear volume of the bottom-port MEMS microphone. In addition, micromechanical module 100 of FIG. 4 has two MEMS acceleration sensors 20A and 20B whose measurement axes 21A, 21B are perpendicular to one another and span a plane parallel to surface 64 of body 60.

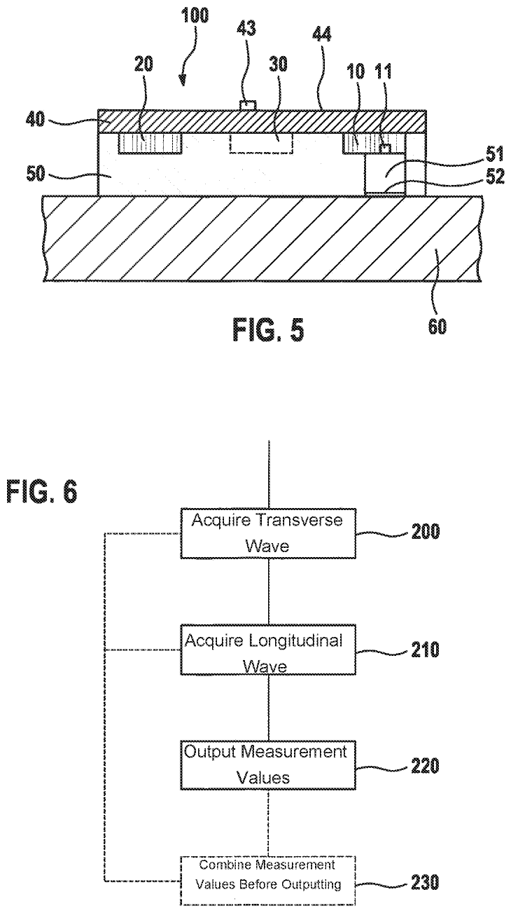

The specific embodiment of FIG. 5 differs from the specific embodiment of FIG. 1 in that microphone 10, MEMS acceleration sensor 20, and the optional evaluation unit 30 are situated on a side of substrate 40 facing body 60 inside housing 50. Microphone 10 is realized as a top-port MEMS microphone and is coupled acoustically directly to cavity 51. The direct acoustic coupling to cavity 51 without opening 41 improves an acoustic coupling compared to the specific embodiment of FIG. 1, and has a slimmer shape. The common interface 43 can be fashioned on a rear side 44 of the substrate by a via in the circuit board.

FIG. 6 shows a schematic flow diagram of a specific embodiment of a method for acquiring oscillations in a body, in particular for acquiring structure-borne sound. In a step 200, a transverse wave of the oscillation is acquired by a microphone. In a step 210, a longitudinal wave of the oscillation is acquired by a MEMS acceleration sensor. Measurement values of the acquired longitudinal and transverse waves of the oscillations are then outputted in a step 220. In an optional step 230, the acquired measurement values of the transverse and longitudinal waves are combined before being outputted, and are then outputted as combined measurement values in a common output signal, in step 220.

1.-14. (canceled)

15. A micromechanical module for placement on a body for acquiring oscillations in the body, comprising:
a housing having a cavity that includes an acoustically operative volume;
a substrate;
a microphone acoustically coupled to the cavity and for acquiring transverse waves of the oscillations; and
a MEMS acceleration sensor for acquiring longitudinal waves of the oscillations along at least one measurement axis parallel to a surface of the body, wherein:
the substrate connects the microphone and the MEMS acceleration sensor to one another electrically and mechanically, and
the substrate includes a common interface for an output.

16. The micromechanical module as recited in claim 15, further comprising:
an evaluation unit, wherein the evaluation unit combines measurement values of the acquired longitudinal and transverse waves and outputs the combined measurement values in a common output signal.

17. The micromechanical module as recited in claim 16, wherein the evaluation unit wirelessly outputs the common output signal.

18. The micromechanical module as recited in claim 15, wherein at least one of the microphone and the MEMS acceleration sensor outputs digital output signals.

19. The micromechanical module as recited in claim 15, wherein the microphone is an MEMS microphone.

20. The micromechanical module as recited in claim 15, wherein the MEMS acceleration sensor is optimized for a first frequency range, and wherein the microphone is optimized for a second frequency range different from the first frequency range.

21. The micromechanical module as recited in claim 15, wherein the MEMS acceleration sensor is optimized for a frequency range between 20 kHz and 100 kHz, and wherein the microphone is optimized in a frequency range up to 20 kHz.

22. The micromechanical module as recited in claim 15, wherein the MEMS acceleration sensor is optimized in a frequency range up to 20 kHz, and wherein the microphone is optimized in a frequency range of 20 kHz and 100 kHz.

23. The micromechanical module as recited in claim 15, wherein the MEMS acceleration sensor includes two measurement axes that are perpendicular to one another and that are oriented parallel to the surface of the body when the micromechanical module is placed on the surface of the body.

24. The micromechanical module as recited in claim 23, wherein the MEMS acceleration sensor includes two MEMS acceleration modules, each MEMS acceleration module having a respective one of the two measurement axes.

25. A method for acquiring oscillations in a body on a surface of the body, comprising:
acquiring transverse waves of the oscillations by a microphone;
acquiring longitudinal waves of the oscillations by a MEMS acceleration sensor; and
outputting measurement values of the acquired transverse waves and the acquired longitudinal waves via a common interface.

26. The method as recited in claim 25, further comprising:
combining the measurement values of the acquired transverse waves and the acquired longitudinal waves before the outputting; and
outputting the combined measurement values as a common output signal.

27. The method as recited in claim 25, wherein the outputting is performed wirelessly.

28. The method as recited in claim 25, wherein at least one of:
the acquiring of the transverse waves includes digitizing the measurement values, and
the acquiring of the longitudinal waves includes digitizing the measurement values.
